(19) United States
(12) Patent Application Publication
(10) Pub. No.: US 2009/0057764 A1
(43) Pub. Date: Mar. 5, 2009

(54) THIN FILM TRANSISTOR AND DISPLAY APPARATUS

(76) Inventors: Takashi OKADA, Kumagaya-shi (JP); Genshiro Kawachi, Chiba-shi (JP)

Correspondence Address: OBLON, SPIVAK, MCCLELLAND MAIER & NEUSTADT, P.C., 1940 DUKE STREET, ALEXANDRIA, VA, 22314, US

(21) Appl. No.: 12/252,910

(22) Filed: Oct. 16, 2008

Related U.S. Application Data
(63) Continuation of application No. PCT/JP07/67050, filed on Aug. 31, 2007.

(30) Foreign Application Priority Data
Feb. 16, 2007 (JP) 2007-037029
Aug. 28, 2007 (JP) 2007-221417

(51) Int. Cl. H01L 29/786

(52) U.S. Cl. 257/347; 257/E29.273

(57) ABSTRACT

A thin film transistor includes a crystal growth region in which a crystal is two-dimensionally grown on a plane, a source region and a drain region formed in the crystal growth region, and a gate electrode which is formed on a channel region between the source region and the drain region through a gate insulator film. The thin film transistor is characterized in that a side end portion on the channel region of the source region or drain region is aligned with a position located within a range of 1 μm to 3.5 μm away from a crystal growth start position.

### CROSS REFERENCE TO RELATED APPLICATIONS

This is a Continuation Application of PCT Application No. PCT/JP2007/067050, filed Aug. 31, 2007, which was published under PCT Article 21(2) in Japanese.

This application is based upon and claims the benefit of priority from prior Japanese Patent Applications No. 2007-037029, filed Feb. 16, 2007; and No. 2007-221417, filed Aug. 28, 2007, the entire contents of both of which are incorporated herein by reference.

### BACKGROUND OF THE INVENTION

1. Field of the Invention

The present invention relates to a Thin Film Transistor (hereinafter referred to as TFT) and a display apparatus. A TFT according to the invention is expected to be used in a display unit, a scanning unit, and a control unit of a display apparatus such as a liquid crystal display and electroluminescence display. Accordingly, a high-performance display apparatus can be produced.

2. Description of the Related Art

As is well known, there is a method for placing a channel region in a thin film transistor in a lateral crystal growth region when the thin film transistor is produced using a crystal the growth direction in a particular one-dimensional direction on a plane of which is controlled (for example, see Surface Science Vol. 21, No. 5, pp. 278-287, 2000).

FIG. 1 is an explanatory view showing a placement method in which a TFT including a source region (S), a drain region (D), and a gate electrode (G) is produced using a conventional one-dimensional growth crystal. As shown in FIG. 1, a crystal growth direction L₂ is made to be parallel to a TFT channel length direction L₁, that is, a current passage direction. This can minimize an effect that many grain boundaries existing in parallel with the crystal growth direction L₂ obstruct the current passed through the TFT. In FIG. 1, the letter S₁ designates a neighborhood of crystal growth start, the letter S₂ designates a lateral crystal growth region, the letter S₃ designates a neighborhood of crystal growth end, and the letter P designates a TFT channel center position. In FIG. 1, a whole region (shaded portion) A of a TFT channel portion is placed in the lateral crystal growth region S₂.

In a crystal in which the crystal growth direction is controlled to take place in a particular one-dimensional direction on a plane, that is, a one-dimensional growth crystal, the crystalline morphology acquires a needle crystal array when a thickness of a semiconductor thin film to be crystallized is about 60 nm or less. Therefore, a one-pulse laser beam is modulated into light having a strong and weak light intensity distribution, and the semiconductor thin film to be crystallized is irradiated with the light, whereby a shape of the crystal grain becomes an array in which many grain boundaries exist in parallel with the crystal growth direction. Usually an interval between the grain boundaries is as narrow as 1 μm or less, and a site and the interval of the generated grain boundaries cannot be controlled. Therefore, in the case where a TFT is produced in the region where the crystallization is performed in the above-described manner, moving directions of electrons and holes moved in the TFT channel region and the grain boundary obliquely intersect each other, which obstructs the current passed through TFT. In order to minimize this effect, the crystal growth direction is made to be parallel to a TFT channel length direction, that is, the current direction.

However, even if the crystal growth direction is parallel to the TFT channel length direction, the decrease in electric characteristics of TFT and the fluctuation in electric characteristics cannot sufficiently be restrained due to the effect of the grain boundary. This is attributed to the following facts. That is, the grain boundary at an interval of 1 μm or less in the TFT channel width direction traverses the channel width. For example, in the case of a TFT having a channel width of 2 μm, 2 to 4 grain boundaries exist in the channel width direction, which decreases the electric characteristic of the TFT. Additionally, because the interval between the grain boundaries also fluctuates, unfortunately the fluctuation in electric characteristic becomes larger.

On the other hand, in a crystal in which omnidirectional crystal growth takes place on a plane, that is, a two-dimensional growth crystal grain, ideally, single crystal grains are regularly spread at a particular interval on the plane. The single crystal grains can be formed to have a square shape of a size of 5 μm. Accordingly, from the viewpoint of area, the whole region of the TFT channel portion can sufficiently be accommodated in one crystal grain. Therefore, the decrease and fluctuation in electric characteristics caused by the grain boundary existing in the TFT channel portion are suppressed unlike the problem of one-dimensional growth crystal.

The inventors of the present invention have developed an industrial mass production technique for forming TFTs in a two-dimensional growth crystal grain. As a result, it is found that the crystalline state depends on the site even in one two-dimensional growth crystal grain and the fluctuation is increased according to the placement method. Specifically, the neighborhood of the crystal growth start point, the neighborhood of the grain boundary, and the lateral crystal growth region are clearly different from one another in the characteristic. That is, the characteristic is extremely deteriorated in the neighborhood of the crystal growth start point and the neighborhood of the grain boundary. Therefore, depending on the placement method, unfortunately the fluctuation cannot sufficiently be decreased compared with a one-dimensional growth crystal.

### BRIEF SUMMARY OF THE INVENTION

In view of the foregoing, an object of the invention is to provide a thin film transistor, in which the electric characteristic is better than that of a TFT produced using the one-dimensional growth crystal and the fluctuation can be minimized by devising a method for placing a TFT using the two-dimensional growth crystal grain.

In order to achieve the above-described object, a thin film transistor according to a first embodiment of the invention comprises a crystal growth region in which a crystal is two-dimensionally grown on a plane, a source region and a drain region in which at least a channel region is provided so as to be aligned with the crystal growth region, and a gate electrode which is formed on a channel region between the source region and the drain region through a gate insulator film, wherein a side end portion on the channel region side of the source region or drain region is aligned with a position located within a range of 1 μm to 3.5 μm away from a crystal growth start position.

A thin film transistor according to a second embodiment of the invention comprises a crystal growth region in which a crystal is two-dimensionally grown on a plane, a source region and a drain region in which at least a channel region is provided so as to be aligned with the crystal growth region, and a gate electrode which is formed on a channel region between the source region and the drain region through a gate insulator film, wherein a current is passed in a crystal growth direction of the crystal growth region in the thin film transistor, and the thin film transistor is formed in a region of one of angles formed between the crystal growth direction and a current direction ranging from 0° to 45°, 135° to 225°, and 315° to 360°.

According to the invention, the electric characteristics are better than that of a TFT produced using a one-dimensional growth crystal, and the fluctuation in characteristic among the formed TFTs can be minimized.

### BRIEF DESCRIPTION OF THE SEVERAL VIEWS OF THE DRAWING

FIG. 1 is an explanatory view showing a placement method in which a TFT is produced using a conventional one-dimensional growth crystal.

FIG. 2 is an explanatory view showing a position of an N-ch TFT channel portion in a two-dimensional crystal grain.

FIG. 3 is a view showing a correlation between an XY coordinate and mobility μmax of the TFT of FIG. 2.

FIG. 4 is a view showing a correlation between an XY coordinate and a threshold voltage Vth of the TFT of FIG. 2.

FIG. 5 is an explanatory view showing a position of an N-ch TFT channel portion in a two-dimensional crystal grain.

FIG. 6 is a view showing a relationship between mobility μmax and change in angle θ and distance R of the TFT of FIG. 5, and a relationship between a threshold voltage Vth and change in angle θ and distance R of the TFT of FIG. 5.

FIG. 7 is an explanatory view showing a position of an N-ch TFT channel portion in a two-dimensional crystal grain.

FIG. 8 is a view showing a correlation between an X coordinate and mobility μmax of the TFT of FIG. 7.

FIG. 9 is a view showing a correlation between an X coordinate and a threshold voltage Vth of TFT of FIG. 7.

FIG. 10 is an explanatory view showing a position of an N-ch TFT channel portion in a two-dimensional crystal grain.

FIG. 11 is a view showing a correlation between a Y coordinate and μmax of the TFT of FIG. 10.

FIG. 12 is a view showing a correlation between a Y coordinate and a threshold voltage Vth of the TFT of FIG. 10.

FIG. 13 is an explanatory view showing a position of an N-ch TFT channel portion in a two-dimensional crystal grain.

FIG. 14 is a view showing a correlation between an angle θ and mobility μmax of the TFT of FIG. 12.

FIG. 15 is a view showing a correlation between an angle θ and a threshold voltage Vth of the TFT of FIG. 12.

FIG. 16 is an explanatory view showing a position of a TFT channel portion in a two-dimensional crystal grain.

FIG. 17 is a view showing a correlation between an X coordinate and μmax of the TFT of FIG. 16.

FIG. 18 is a view showing a correlation between an X coordinate and a threshold voltage Vth of the TFT of FIG. 16.

FIG. 19 is an explanatory view showing a position of a P-ch TFT channel portion in a two-dimensional crystal grain.

FIG. 20 is a view showing a correlation between an X coordinate and mobility μmax of the TFT of FIG. 19.

FIG. 21 is a view showing a correlation between an X coordinate and a threshold voltage Vth of the TFT of FIG. 19.

FIG. 22 is an explanatory view showing a position of a P-ch TFT channel portion in a two-dimensional crystal grain.

FIG. 23 is a view showing a correlation between a Y coordinate and mobility μmax of the TFT of FIG. 22.

FIG. 24 is a view showing a correlation between a Y coordinate and a threshold voltage Vth of the TFT of FIG. 22.

FIG. 25 is a partial cross-sectional view showing a method for producing a TFT according to the processing order of the invention.

FIG. 26 is a partial cross-sectional view showing the method for producing a TFT according to the processing order of the invention.

FIG. 27 is a partial cross-sectional view showing the method for producing TFT according to the processing order of the invention.

FIG. 28 is a view schematically showing a configuration of a crystallization apparatus for forming a semiconductor film having a two-dimensional growth crystal grain in which a TFT according to the invention is formed.

FIG. 29 is a view schematically showing an internal configuration of an illumination system of FIG. 28.

FIG. 30 is a view showing a configuration of a position modulation element of the crystallization apparatus of FIG. 28.

FIG. 31 is a view showing light intensity distributions corresponding to transversal lines X-X, Y-Y, and Z-Z of a unit region of FIG. 30.

FIG. 32 is a view showing light intensity distributions corresponding to transversal lines X-X, Y-Y, and Z-Z of a unit region of FIG. 30, the intensity distributions exhibiting modes different from those of FIG. 31.

FIG. 33 is an explanatory view showing a placement method in which a TFT is placed in one two-dimensional growth crystal grain in a first embodiment of the invention.

FIG. 34 is an explanatory view showing a placement method in which a TFT is placed in one two-dimensional growth crystal grain in a second embodiment of the invention.

FIG. 35 is an explanatory view showing a placement method in which a TFT is placed in one two-dimensional growth crystal grain in a third embodiment of the invention.

FIG. 36 is an explanatory view showing a placement method in which a TFT is placed in one two-dimensional growth crystal grain in a fourth embodiment of the invention.

FIG. 37 is an explanatory view showing a placement method in which a TFT is placed in one two-dimensional growth crystal grain in a fifth embodiment of the invention.

FIG. 38 is an explanatory view showing a placement method in which a TFT is placed in one two-dimensional growth crystal grain in a sixth embodiment of the invention.

FIG. 39 is an explanatory view showing a placement method in which a TFT is placed in one two-dimensional growth crystal grain in a seventh embodiment of the invention.

FIG. 40 is an explanatory view showing a placement method in which a TFT is placed in one two-dimensional growth crystal grain in an eighth embodiment of the invention.

FIG. 41 is an explanatory view showing a placement method in which a TFT is placed in one two-dimensional growth crystal grain in a ninth embodiment of the invention.

FIG. 42 is an explanatory view showing a placement method in which a TFT is placed in one two-dimensional growth crystal grain in a tenth embodiment of the invention.

FIG. 43 is an explanatory view showing an example of a display apparatus according to an eleventh embodiment of the invention.

### DETAILED DESCRIPTION OF THE INVENTION

An embodiment of a Thin Film Transistor (TFT) according to the invention will be described in detail.

The embodiment of a TFT including a crystal growth region where a crystal is two-dimensionally grown on a plane, a source region and a drain region where at least a channel region is provided so as to be aligned with the crystal growth region, and a gate electrode which is formed on a channel region between the source region and the drain region through a gate insulator, is characterized in that a side end portion on the channel region side of the source region or drain region is aligned with a position located within a range of 1 μm to 3.5 μm away from a crystal growth start position.

After the inventors investigated how TFT T1 is placed for the above-described correlation between the two-dimensional growth crystal grain K1 and the TFT characteristic, the inventors obtained correlations shown in FIGS. 2 to 4. FIG. 2 shows a state in which a channel position of an N-ch TFT T1 is placed while changed in an X coordinate and a Y coordinate within a range of −4 [μm] to +4 [μm] at an interval of 1.0 [μm]. In FIG. 2, a channel length direction L₁ is set at an X-axis and a channel width direction is set at a Y-axis. In FIG. 2, the letter P designates a channel center position and the letter L₂ designates a crystal growth direction.

FIG. 3 is a view showing a relationship between an XY coordinate position and μmax (maximum mobility for gate voltage). In FIG. 3, which is a view showing a TFT characteristic, an average of N=11 is shown for each coordinate by a two-dimensional plot, the letter S1 designates a neighborhood of a growth start point, the letter S2 designates a lateral crystal growth region, and the letter S3 designates a neighborhood of a growth end point (grain). In FIG. 3, the letter a designates a μmax region of 250 to 300, the letter b designates a μmax region of 200 to 250, the letter c designates a μmax region of 150 to 200, the letter d designates a μmax region of 100 to 150, the letter e designates a μmax region of 50 to 100, and the letter f designates a μmax region of 0 to 50 (in units of cm²/v·s).

FIG. 4 shows a relationship between an XY coordinate position and a threshold voltage (Vth) which is a gate voltage at the beginning of passage of a current through a TFT (TFT characteristic is evaluated and an average of N=11 is two-dimensionally plotted for each coordinate). In FIG. 4, S1, S2, and S3 designate the same things as those of FIG. 2. However, in FIG. 2, the letter a designates a threshold voltage Vth ranging from 1.5 to 1.6, the letter b designates a threshold voltage Vth ranging from 1.4 to 1.5, the letter c designates a threshold voltage Vth ranging from 1.3 to 1.4, the letter d designates a threshold voltage Vth ranging from 1.2 to 1.3, the letter e designates a threshold voltage Vth ranging from 1.1 to 1.2, and the letter f designates a threshold voltage Vth ranging from 1.0 to 1.1 (in units of V).

As can be seen from FIGS. 2 to 4, a region having a distance of 1 μm or less from the crystal growth start point has a poor characteristic because the region is located in a polycrystalline region, a region having a distance of 3.5 μm or more also has a poor characteristic because the region is located near the grain boundary, and a region has a good characteristic in the range of 1 μm to 3.5 μm. The reason why the characteristic is improved the closer the region is to the X-axis is that the effect of the grain boundary drops with the decrease in the angle formed between the TFT channel direction and the lateral crystal growth direction.

FIG. 5 is an explanatory view showing a model for explaining the correlation shown in FIGS. 3 and 4. FIG. 5 shows the case of an 8×8-μm-cushion-shape crystal grain K1 in which the crystal is grown in a radial manner (broken-line arrow) from the crystallization start position (point) at which the X-axis and the Y-axis intersect each other. FIG. 5 shows an embodiment in which a TFT is formed such that electrons or holes moved in the TFT channel region are moved in a direction of 45 degrees relative to the X-axis or Y-axis. FIG. 6A shows a relationship between mobility μmax and change in angle θ and distance R between a TFT channel position and the crystallization start point (XY coordinate (0,0)) based on FIG. 5. Similarly, FIG. 6B shows a relationship between the threshold voltage Vth and the change in distance R and angle θ (the TFT characteristic is evaluated and an average of N=11 is two-dimensionally plotted for each coordinate). However, in the evaluation of the dependence of the TFT on position, the TFT characteristic is evaluated for the TFT channel position in which R is changed from 2.0 [μm] to 3.5 [μm] at an interval of 0.5 [μm] while θ is changed from 0° to 360° at an interval of 45°, and an average of N=11 is two-dimensionally plotted for each coordinate.

That is, FIGS. 5, 6A, and 6B show the correlation between the N-ch TFT characteristic and position of the TFT channel portion in the two-dimensional growth crystal grain. FIGS. 5, 6A, and 6B also show the dependence in a so-called polar coordinate system in which distance (R) from the crystallization start point and angle (θ) formed between the X-axis and the TFT channel length direction L₁ are changed. However, θ is changed while the crystal growth direction and the TFT channel length direction are always kept parallel to each other. It is considered that the R range of 2.0 μm to 3.5 μm is the substantially lateral crystal growth region. Although the characteristic is not definite, because a fluctuation exists in actual data, a good characteristic is obtained at least within the range of 2.0 μm to 3.5 μm.

In FIG. 6A, the letter a designates a μmax region of 300 to 350, the letter b designates a μmax region of 250 to 300, the letter c designates a μmax region of 200 to 250, the letter d designates a μmax region of 150 to 200, the letter e designates a μmax region of 100 to 150, the letter f designates a μmax region of 50 to 100, and the letter g designates a μmax region of 0 to 50 (in units of cm²/v·s). In FIG. 6B, the letter a designates a threshold voltage Vth ranging from 3.0 to 3.5, the letter b designates a threshold voltage Vth ranging from 2.5 to 3.0, the letter c designates a threshold voltage Vth ranging from 2.0 to 2.5, the letter d designates a threshold voltage Vth ranging from 1.5 to 2.0, the letter e designates a threshold voltage Vth ranging from 1.0 to 1.5, and the letter f designates a threshold voltage Vth ranging from 0.5 to 1.0 (in units of V).

FIG. 7 is a plan view showing the correlation between the N-ch TFT characteristic and position of the N-ch TFT channel portion in a two-dimensional growth crystal grain, and FIG. 7 shows the case of an 8×8-μm-cushion-shape crystal. FIG. 8 shows a relationship between a TFT mobility μmax and a distance X from crystallization start point P₁ based on FIG. 7 to the position in the TFT channel direction. Similarly, FIG. 9 shows a relationship between the distance X and the gate voltage at the beginning of the start of the drain current, that is, the threshold voltage Vth. In FIG. 8, the letter S₁ designates a neighborhood of the growth start point (μmax<200) and the letter S₂ designates a lateral crystal growth region (μmax>100). In FIG. 9, the letter S₁ designates a polycrystalline region (Vth>1.0V) near the growth start point and the letter S₂ designates a lateral crystal growth region (Vth<1.7V). However, in the evaluation of dependence of the TFT on the position, the TFT characteristic is evaluated for the TFT channel position in which the X coordinate is changed from −4 [μm] to +4 [μm] at an interval of 0.5 [μm] while the Y coordinate is fixed to 0 [μm], and μmax and the threshold voltage Vth are plotted for the X coordinate.

In FIGS. 7 to 9, the channel position is made to be parallel to the TFT channel length direction (X-direction) while the crystal growth start point is set at an origin in the case where the channel position is made to be parallel to the TFT channel length direction (X-direction) while the crystal growth start point of TFT of FIG. 7 is set at an origin. In such cases, a region having a distance of 2 μm or less from the crystal growth start point O has a poor characteristic because the region is located in the polycrystalline region, and a region also having a distance of 3.5 μm or more has a poor characteristic because the region is located near the grain boundary. It is found that the region has a good mobility characteristic and threshold voltage characteristic in the range of 2 μm to 3.5 μm. Although the range of the polycrystalline region depends on the crystallization condition and fluctuation, the polycrystalline region ranges from about 1 μm to about 2 μm.

FIG. 10 is an explanatory view showing a correlation between the N-ch TFT characteristic and the position of the TFT channel portion in the two-dimensional growth crystal grain with respect to only a one-dimensional direction, and FIG. 10 shows the case of the 8×8-μm-cushion-shape crystal K1. FIG. 11 shows a relationship between μmax and a distance Y to the start end position of the channel width when the TFT channel width direction is formed in parallel with the Y-axis from the crystallization start point P₁ based on FIG. 10. Similarly, FIG. 12 shows a relationship between the distance Y and the threshold voltage Vth. In FIGS. 11 and 12, the letter S₁ designates a polycrystalline region near the growth start point and the letter S₂ designates a lateral crystal growth region. As can be seen from FIG. 11, the polycrystalline region S₁ near the start point is substantially equal to the growth region S₂ in μmax. As can be seen from FIG. 12, the polycrystalline region S₁ near the start point is substantially equal to the growth region S₂ in the characteristic of the threshold voltage Vth. However, in the evaluation of dependence of the TFT on the position, the TFT characteristic is evaluated for the TFT channel position in which the Y coordinate is changed from −4 [μm] to +4 [μm] while the X coordinate is fixed to 0 [μm], and μmax and the threshold voltage Vth are plotted for the Y coordinate.

In FIGS. 10 to 12, the channel position is made to be parallel to the TFT channel width direction while the crystal growth start point P₁ is set at an origin. Accordingly, a region having a distance of 1 μm or less from the crystal growth start point P₁ has a poor characteristic because the region is located in the polycrystalline region, the region having a distance of 3.5 μm or more also has a poor characteristic because the region is located near the grain boundary, and it is found that a region has a good characteristic in the range of 1 μm to 3.5 μm. The reason why the characteristic deteriorates in the lateral crystal growth region compared with the case of FIG. 7 is that the TFT channel direction and the crystal growth direction are placed perpendicularly to each other to maximize the effect of the grain boundary.

FIG. 13 shows an embodiment in which the direction of the current passed through the TFT of FIG. 7 is changed from the X-axis to the θ direction. FIG. 13 shows a correlation with the channel direction when the TFT is rotated while the channel position of the N-ch TFT characteristic is fixed to a predetermined lateral crystal growth region on the X-axis. An embodiment of FIG. 13 shows the case of the 8×8-μm-cushion-shape (square) crystal grain K1. In FIG. 13, the letter 0 designates an angle formed between the lateral crystal growth direction (X-axis) and the TFT channel length direction L₁. FIG. 14 shows a relationship between the angle θ and μmax, and FIG. 15 shows a relationship between the angle θ and the threshold voltage Vth. In FIGS. 14 and 15, the letter S₂ designates a lateral crystal growth region in which the angle θ ranges from 0° to 45°, from 135° to 225°, or from 315° to 320°. However, in the evaluation of dependence of the TFT on the position, the TFT characteristic is evaluated for the TFT channel position in which θ is changed from 0° to 360° at an interval of 30° while the X,Y coordinate is fixed to (2,0), and μmax and the threshold voltage Vth are plotted for the angle θ.

In the mobility characteristic shown in FIGS. 13 to 15, the mobility exhibits a good characteristic from FIG. 14 when the angle θ ranges from 0° to 45°, from 135° to 225°, and from 315° or more. The threshold voltage exhibits a good characteristic from FIG. 15 when the angle θ ranges from 0° to 45°, from 135° to 225°, and from 315° or more.

FIG. 16 shows the state in which the P-ch TFT channel position is placed while both the X coordinate and the Y coordinate are changed from −4 [μm] to +4 [μm] at an interval of 1.0 [μm]. In FIG. 16, the X-axis is set in parallel with the channel length direction and the Y-axis is set in parallel with the channel width direction. In FIG. 16, the letters L, L₂, S, D, G, and P designate the same things as those of FIG. 2.

FIG. 17 shows a relationship between the XY coordinate and μmax (the TFT characteristic is evaluated and an average of N=11 is two-dimensionally plotted for each coordinate). In FIG. 17, the letters S₁, S₂, and S₃ designate the same things as those of FIG. 3. In FIG. 17, the letter a designates a μmax region of 80 to 90, the letter b designates a μmax region of 70 to 80, the letter c designates a μmax region of 60 to 70, the letter d designates a μmax region of 50 to 60, the letter e designates a μmax region of 40 to 50, the letter f designates a μmax region of 30 to 40, the letter g designates a μmax region of 20 to 30, and the letter h designates a μmax region of 10 to 20 (in units of cm²/v·s).

FIG. 18 shows a relationship between a position in the XY direction and the threshold voltage (Vth) (the TFT characteristic is evaluated and an average of N=11 is two-dimensionally plotted for each coordinate). In FIG. 18, the letters S₁, S₂, and S₃ designate the same things as those of FIG. 3. However, in FIG. 18, the letter a designates a threshold voltage Vth ranging from −1.5 to −1.0, the letter b designates a threshold voltage Vth ranging from −2.0 to −1.5, the letter c designates a threshold voltage Vth ranging from −2.5 to −2.0, the letter d designates a threshold voltage Vth ranging from −3.0 to −2.5, the letter e designates a threshold voltage Vth ranging from −3.5 to −3.0, and the letter f designates a threshold voltage Vth ranging from −4.0 to −3.5 (in units of V).

In FIGS. 16 to 18, the region having a distance of 1 μm or less from the crystal growth start point has poor μmax and Vth characteristics because the region is located in the polycrystalline region, and the region having a distance of 3.5 μm or more also has poor μmax and Vth characteristics because the region is located near the grain boundary, and it is found that the region has good μmax and Vth characteristics in the range of 1 μm to 3.5 μm. The reason why the μmax and Vth characteristics are improved the closer the region is to the X-axis is that the effect of the grain boundary is decreased the smaller the angle formed between the TFT channel direction and the lateral crystal growth direction is.

FIG. 19 shows a correlation between the P-ch TFT characteristic and the position of the TFT channel portion in the two-dimensional growth crystal grain, and FIG. 19 shows the case of the 8×8-μm-cushion-shape crystal grain K1. FIG. 20 shows a relationship between μmax and a distance between a position in the TFT channel direction and the crystallization start point P₁ based on FIG. 19. Similarly, FIG. 21 shows a relationship between the distance and the threshold voltage Vth. In FIG. 20, the letter S₁ designates a polycrystalline region (μmax<80) near the growth start point and the letter S₂ designates a lateral crystal growth region (μmax>60). In FIG. 21, the letter S₁ designates a polycrystalline region (Vth<−1.0V) near the growth start point and the letter S₂ designates a lateral crystal growth region (Vth>−2.0V). However, in the evaluation of the dependence of the TFT on the position, the TFT characteristic is evaluated for a TFT channel position in which the X coordinate is changed from −4 [μm] to +4 [μm] at an interval of 0.5 [μm] while the Y coordinate is fixed to 0 [μm], and μmax and the threshold voltage Vth are plotted for the X coordinate. As can be seen from FIG. 20, a difference in mobility becomes larger in the region S₁ near the start point and the growth region S₂. As can be seen from FIG. 21, a difference in threshold voltage becomes larger in the region S₁ near the start point and the growth region S₂.

In FIGS. 19 to 21, when the channel position is made to be parallel to the TFT channel length direction L₁ while the crystal growth start point P₁ is set at the origin, the region having a distance of 2 μm or less from the crystal growth start point P₁ has a poor characteristic because the region is located in the polycrystalline region, the region having a distance of 3.5 μm or more also has a poor characteristic because the region is located near the grain boundary, and it is found that the region has a good characteristic in the range of 2 μm to 3.5 μm. Although the range of the polycrystalline region depends on the crystallization condition and fluctuation, the polycrystalline region ranges from about 1 μm to about 2 μm.

FIG. 22 is an explanatory view showing a correlation between the P-ch TFT characteristic and the position of the TFT channel portion in the two-dimensional growth crystal grain with respect to only a one-dimensional direction, and FIG. 22 shows the case of the 8×8-μm-cushion-shape crystal grain K1. FIG. 23 shows a relationship between μmax and a distance Y between the position in the TFT channel width direction and the crystallization start point P₁ based on FIG. 22. Similarly, FIG. 24 shows a relationship between the distance Y and the threshold voltage Vth. In FIGS. 23 and 24, S₁, S₂, and S₃ designate the same things as those of FIG. 8.

As can be seen from FIGS. 22 to 24, when the channel position is made to be parallel to the TFT channel width direction while the crystal growth start point P₁ is set at an origin, the region having a distance of 1 μm or less from the crystal growth start point P₁ has a poor characteristic because the region is located in the polycrystalline region, the region having a distance of 3.5 μm or more also has a poor characteristic because the region is located near the grain boundary, and it is found that the region has a good characteristic in the range of 1 μm to 3.5 μm. The reason why the characteristic is deteriorated in the lateral crystal growth region compared with the case of FIG. 19 is that the P-ch TFT channel direction L₁ and the crystal growth direction L₂ are placed perpendicularly to each other to maximize the effect of the grain boundary.

The invention satisfies the necessary conditions of the following configurations (1) and (2).

(1) A thin film transistor comprising a crystal growth region in which a crystal is two-dimensionally grown on a plane, a source region and a drain region in which at least a channel region is provided so as to be aligned with the crystal growth region, and a gate electrode which is formed on a channel region between the source region and the drain region through a gate insulator film, wherein a side end portion on the channel region side of the source region or drain region is aligned with a position located within a range of 1 μm to 3.5 μm away from a crystal growth start position.

(2) A thin film transistor comprising a crystal growth region in which a crystal is two-dimensionally grown on a plane, a source region and a drain region in which at least a channel region is provided so as to be aligned with the crystal growth region, and a gate electrode which is formed on a channel region between the source region and the drain region through a gate insulator film, wherein a current is passed in a crystal growth direction of the crystal growth region in the thin film transistor, and the thin film transistor is formed in a region of one of angles formed between the crystal growth direction and a current direction ranging from 0° to 45°, 135° to 225°, and 315° to 360°.

Therefore, a merit of TFT production with the two-dimensional growth crystal grain can be maximized. As a result, the electric characteristics become better than those of a TFT produced with the one-dimensional growth crystal, and the fluctuation can be minimized. Preferably, the source region, the drain region, and the channel region are formed in the crystal growth region of a virtual region passing through a central portion of the crystal growth region and the middle of each side.

Thus, a TFT is formed in the range in which the angle formed between the crystal growth direction and the current direction falls within the above-described range, which allows good TFT characteristics to be obtained, as in (1).

### [TFT Production Method]

A TFT production method according to the invention will be described with reference to FIGS. 25A to 25G, FIGS. 26H to 26O, and FIGS. 27P to 27U. However, the invention is not limited to the following production method. An embodiment in which the production method is applied to production of a TFT for a liquid crystal display will be described below.

1) First, an underlying oxide film (SiO₂ film) 22 having a film thickness of 800 nm is formed on a liquid crystal display producing glass substrate 21 at a substrate temperature of 500° C. for a deposition time of 40 minutes by a plasma CVD technique (see FIG. 25A). Then, an active layer forming a-Si (amorphous silicon) film 23 having a film thickness of 100 nm is formed at a substrate temperature of 450° C. for a deposition time of 70 minutes by an LP (low pressure)-CVD technique while Si₂H₆ gas is supplied at a flow rate of 150 cccm at a pressure of 8 Pa. Then, boron is doped as a dopant by an ion shower doping technique (see FIG. 25B).

2) The a-Si film 23 is irradiated at an intensity of 350 mJ/cm² using a KrF (krypton fluoride) excimer laser beam 24 (see FIG. 25C). At this point, the a-Si film 23 is irradiated with a laser beam having a concentric sectional shape in which the laser beam intensity is weakened in the center while strengthened in the periphery, thereby obtaining a disc-shape polycrystalline silicon film 25 formed by crystal grains of a large size. Then, a protective oxide film (SiO₂ film) 26 having a film thickness of 10 nm is formed on the polycrystalline silicon film 25 at a substrate temperature of 500° C. for a deposition time of 10 minutes by an LP-CVD technique (see FIG. 25D).

3) A resist material is applied onto the protective oxide film 26, and exposure and development are performed to form a resist film 27 in which patterning is performed (see FIG. 25E). Then, using the resist film 27 as a mask, the protective oxide film 26 and the polycrystalline silicon film 25 are selectively removed by a dry etching technique in which BCl₃+CH₄ gas is used (see FIG. 25F). Then, the resist film 27 is removed (see FIG. 25G).

4) A gate oxide film (SiO₂ film) 28 having a film thickness of 100 nm is formed at a substrate temperature of 500° C. for a deposition time of 60 minutes by an LP-CVD technique (see FIG. 26H). In FIG. 26H, because the protective oxide film is made of the same material (SiO₂) as the gate oxide film, the protective oxide film is not shown. Then, a gate electrode forming Mo (molybdenum) film 29 having a film thickness of 100 nm is formed on the gate oxide film 28 at a substrate temperature of 100° C. for a deposition time of 10 minutes by a sputtering method (see FIG. 26I). Then, a resist material is applied onto the Mo film 29, and the exposure and development are performed to form a resist film 30 in which the patterning is performed (see FIG. 26J).

5) Then, using the resist film 30 as a mask, the Mo film 29 is selectively removed to form a gate electrode 31 by the dry etching technique in which BCl₃+CH₄ gas is used (see FIG. 26K). Then, after the resist film 30 is removed, as shown in FIG. 26L, a passivation film (SiO₂ film) 32 having a film thickness of 200 nm is formed at a substrate temperature of 500° C. for a deposition time of 20 minutes by the plasma CVD technique (see FIG. 26M).

6) A resist material is applied onto the passivation film 32, and the exposure and development are performed to form a resist film 33 in which the patterning is performed (see FIG. 26N). Then, using the resist film 33 as a mask, a contact hole 34 is formed by a dry etching technique in which CHF₃+O₂ gas is used (see FIG. 26O).

7) The resist film 33 is removed as shown in FIG. 27P. Then, ion doping of phosphorus 35 is performed, and activation annealing of the dopant is performed at a temperature of 500° C. for three hours in a nitrogen atmosphere to form a source region 36 and a drain region 37 (see FIG. 27Q). The numeral 38 designates a channel region between the source region 36 and the drain region 37. Al film 39 for an electrode having a film thickness of 100 nm is formed at a substrate temperature of 100° C. for a deposition time of 10 minutes by the sputtering technique (see FIG. 27R).

8) A resist material is applied onto the Al film 39, and the exposure and development are performed to form a resist film 40 in which the patterning is performed (see FIG. 27S). Then, using the resist film 40 as a mask, the Al film 39 is selectively removed to form a source electrode 41, a drain electrode 42, and a gate electrode (extraction electrode of gate electrode 31) 43 by the dry etching technique in which BCl₃+CH₄ gas is used (see FIG. 27T). The resist film 40 is removed to form a thin film transistor 44 (see FIG. 27U).

[Description of Crystallization Apparatus]

A crystallization apparatus 50 forming the two-dimensional growth crystal grain in which TFT according to the invention is formed will be described below with reference to FIGS. 28, 29, 30, 31A to 31C, and 32A to 32C. However, the crystal growth method of the invention is not limited to the following method. FIG. 28 is a view schematically showing a configuration of the crystallization apparatus, and FIG. 29 is a view schematically showing an internal configuration of an illumination system of FIG. 28.

As shown in FIGS. 28 and 29, the crystallization apparatus used in the invention includes a phase modulation element 51 and a luminous flux dividing element 52. The phase modulation element 51 performs phase modulation of an incident luminous flux to form a luminous flux having a predetermined light intensity distribution. The luminous flux dividing element 52 divides the incident luminous flux into two incoherent fluxes having different polarization states. At this point, the phase modulation element 51 is disposed close to the luminous flux dividing element 52 such that a phase pattern surface (surface having a step) of the phase modulation element 51 faces the luminous flux dividing element 52. Alternatively, the phase modulation element 51 and the luminous flux dividing element 52 may integrally be formed. Configurations and actions of the phase modulation element 51 and luminous flux dividing element 52 are described later.

The crystallization apparatus 50 further includes an illumination system 53 with which the phase modulation element 51 is illuminated. For example, the illumination system 53 includes a KrF excimer laser light source 53a which emits light having a wavelength of 248 nm in an optical system shown in FIG. 29. Other appropriate light sources, such as a XeCl excimer laser light source or a YAG laser light source, which have are capable of emitting an energy beam for melting a material to be crystallized can be used as the light source 53a. The laser beam emitted from the light source 53a is expanded through a beam expander 53b, and then passes through a first fly-eye lens 53c. Thus, plural light sources are formed in a focal plane on a rear side of the first fly-eye lens 53c, and a plane of incidence of a second fly-eye lens 53e is illuminated in an overlapping manner through a first condenser optical system 53d with the luminous fluxes from the plural light sources.

Accordingly, more light sources than those in the focal plane on the rear side of the first fly-eye lens 53c are formed in a focal plane on a rear side of the second fly-eye lens 53e. The phase modulation element 51 is illuminated in an overlapping manner through second condenser optical system 53f and an iris 53g with the luminous fluxes from the plural light sources formed in the focal plane on the rear side of the second fly-eye lens 53e. At this point, the first fly-eye lens 53c and the first condenser optical system 53d constitute a first homogenizer. The first homogenizer achieves homogenization of the incident angles on the phase modulation element 51 for the laser beam emitted from the light source 53a.

The second fly-eye lens 53e and the second condenser optical system 53f constitute a second homogenizer. The second homogenizer achieves homogenization of the light intensity at each position in the plane of the phase modulation element 51 for the laser beam whose incident angle is homogenized by the first homogenizer. A pair of cylindrical fly-eye lenses can be used instead of the first fly-eye lens 53c or second fly-eye lens 53e. The cylindrical fly-eye lens is formed by plural cylindrical lens elements. The plural cylindrical lens elements have a refractive power in a certain plane, and have no refractive power in a plane orthogonal to the plane.

In the illumination system 53, the phase modulation element 51 is illuminated by the laser beam having a substantially homogeneous light intensity distribution. The laser beam to which the phase modulation is performed by the phase modulation element 51 is incident on a processed substrate 55 through an imaging optical system 54. In the imaging optical system 54, a phase pattern plane of the phase modulation element 51 is optically conjugate to the processed substrate 55. In other words, the processed substrate 55 is set on a plane (image surface of imaging optical system 54) optically conjugate to the phase pattern plane of the phase modulation element 51. The imaging optical system 54 includes an aperture stop 54c located between a positive lens group 54a and a positive lens group 54b.

The aperture stop 54c includes plural aperture stops having different sizes of opening portions (light transmission portions). The plural aperture stops 54c may be configured to be exchangeable with respect to an optical path. The aperture stop 54c may include an iris diaphragm which can continuously change the size of the opening portion. As described later, the size of the opening portion of the aperture stop 54c is set so as to generate a required light intensity distribution on the semiconductor film of the processed substrate 55. The imaging optical system 54 may be a refracting optical system, reflection optical system, or a catadioptric optical system.

The processed substrate 55 is formed by sequentially depositing a lower-layer insulator film, a semiconductor thin film, and an upper-layer insulator film on the substrate. In the processed substrate 55, an underlying insulator film, a non-single crystal film such as an amorphous silicon film, and a capping film are sequentially formed, for example, on plate glass for liquid crystal display by a Chemical Vapor Deposition technique. The underlying insulator film and the capping film are formed by an insulating film such as SiO₂. The underlying insulator film prevents the amorphous silicon film and the glass substrate from directly contacting each other, thus avoiding mixing of a foreign material such as Na into the amorphous silicon film, and also prevents a melting temperature of the amorphous silicon film from transferring heat directly to the glass substrate. The amorphous silicon film is a semiconductor film to be crystallized.

The amorphous silicon film absorbs the incident light, part of the absorbed incident light is transferred in the form of heat to the capping film to heat the capping film, and the heat is accumulated in the capping film (heat accumulation effect). When the incidence of the light beam is blocked, a temperature is relatively rapidly lowered in a high-temperature portion of the irradiated surface of the amorphous silicon film. However, the heat accumulation effect suppresses the lowering of temperature to promote large-grain-size crystal growth in a lateral direction. The processed substrate 55 is retained at a predetermined position on a substrate stage 56 by a vacuum chuck or an electrostatic chuck.

A phase shift pattern of the phase modulation element 51, which is used to form the two-dimensional growth crystal grain with the crystallization apparatus 50, will be described below with reference to FIGS. 29 and 30. The phase modulation element 51 is an optical element which performs phase modulation of the incident luminous flux to form a luminous flux having a predetermined light intensity distribution. FIG. 30 is a schematic view showing an enlarged phase shift pattern used to form two reversed-peak light intensity distributions of the phase modulation element 51. The phase shift pattern of the return modulation element 51 is an optical element in which, for example, 40 phase shift patterns shown in FIG. 30 are arranged in a matrix shape in one-pulse laser beam plane. The phase modulation element 51 is an optical element used to form the 5-μm-square two-dimensional growth crystal grain array in the semiconductor thin film. The phase shift patterns shown in FIG. 30 are two-dimensionally arranged at predetermined intervals, and are formed by plural unit regions 57a having the same patterns. For simplification of explanation, FIG. 30 shows two square unit regions 57a adjacent to each other. Each unit region 57a has one side of 5 μm in a corresponding value in the image surface of the imaging optical system 54. Hereinafter, the size of the phase modulation element 51 is expressed by the corresponding value in the image surface of the imaging optical system 54.

The unit region 57a includes a reference surface (blank portion of FIG. 30) 57aa having a given phase, a first phase region 57ab and a second phase region 57ac which are disposed near the center of the unit region 57a, and plural dot regions 57ad which are disposed around the first phase region 57ab and second phase region 57ac. The first phase region 57ab and the second phase region 57ac are fan-like patterns which are obtained by dividing a circle having a radius of 0.5 μm into four, and the first phase region 57ab and the second phase region 57ac are disposed such that apexes contact each other in the center of the unit region 57a.

0.5-μm-square unit cells (not shown) are virtually arranged in a matrix around the first phase region 57ab and second phase region 57ac. The unit cell is smaller than a radius of a point image distribution range of the imaging optical system 54. One dot region 57ad is selectively provided in each unit cell. An occupied area of the dot region 57ad per unit cell is decreased with distance from the contact point (center of the unit region 57a) of the first phase region 57ab and the second phase region 57ac. The first phase region 57ab, the second phase region 57ac, and all the dot regions 57ad have a phase (relative phase difference when a phase in a reference surface 57aa (modulation amount) is normalized at 0 degrees) of +90 degrees with respect to the reference surface 57aa.

At this point, note the light intensity distribution which is formed along a transversal line corresponding to a line X-X traversing the center of the unit region 57a in the surface of the processed substrate 55 positioned at various positions with respect to the imaging optical system 54. As shown in FIG. 31A, a light intensity distribution is formed along the transversal line corresponding to the transversal line X-X of the unit region 57a in the surface of the processed substrate 55 which is positioned defocused by 5 μm from a computed focal position of the imaging optical system 54 (defocusing of +5 μm) in the direction (toward the upper side of FIG. 28) in which the processed substrate 55 is brought 5 μm closer to the imaging optical system 54. As shown in FIG. 31B, a light intensity distribution is formed along the transversal line corresponding to the transversal line Y-Y of the unit region 57a in the surface of the processed substrate 55 positioned at the computed focal position of the imaging optical system 54.

As shown in FIG. 31C, a light intensity distribution is formed along the transversal line corresponding to the transversal line Z-Z of the unit region 57a in the surface of the processed substrate 55 which is positioned defocused by 5 μm from the computed focal position of the imaging optical system 54 (defocusing of −5 μm) in the direction (toward the lower side of FIG. 28) in which the processed substrate 55 is moved away from the imaging optical system 54. As shown in FIG. 32A, a light intensity distribution is formed along the transversal line corresponding to the transversal line X-X of the unit region 57a in the surface of the processed substrate 55 which is positioned defocused by 7 μm from the computed focal position of the imaging optical system 54 (defocusing of −7 μm) in the direction in which the processed substrate 55 is moved away from the imaging optical system 54.

As shown in FIG. 32B, a light intensity distribution is formed along the transversal line corresponding to the transversal line Y-Y of the unit region 57a in the surface of the processed substrate 55 which is positioned defocused by 10 μm from the computed focal position of the imaging optical system 54 (defocusing of −10 μm) in the direction in which the processed substrate 55 is moved away from the imaging optical system 54. Finally, as shown in FIG. 32C, the light intensity distribution is formed along the transversal line corresponding to the transversal line Z-Z of the unit region 57a in the surface of the processed substrate 55 which is positioned defocused by 15 μm from the computed focal position of the imaging optical system 54 (defocusing of −15 μm) in the direction in which the processed substrate 55 is moved away from the imaging optical system 54.

A method for crystallizing the two-dimensional growth crystal grain with the crystallization apparatus 50 will be described below. In the crystallization apparatus 50, the processed substrate 55 positioned by moving the substrate stage 56 is moved to a position at which the processed substrate 55 is crystallized, a computer controls the motion in the Z-direction of the substrate stage 56 using a detection signal from a height sensor, and matches a shift amount between the substrate stage 56 and the processed substrate 55 with a target shift amount.

Then, an attenuator is automatically adjusted based on the readout apparatus parameters. That is, a light intensity distribution measured with a beam profiler and a predetermined target light intensity distribution are compared with each other to compute an attenuator manipulated variable. Then, while feedback is performed such that the intensity which is measured by supplying a manipulated signal to the attenuator becomes the target intensity, an angle of the attenuator is accurately adjusted.

The substrate stage 56 is moved in a stepwise manner at a predetermined interval in the X-Y plane to change the position thereof. Therefore, the desired region of the processed substrate 55 is located at the irradiation position, so that the large-area amorphous silicon film can be crystallized by repeating the X-Y step moving process and the crystallization (annealing) process. This state is displayed on a screen of the display apparatus. Accordingly, an operator can understand in real time which region on the processed substrate 55 is irradiated with the laser beam. A light intensity distribution waveform of the laser beam during the irradiation is also displayed on a screen of the display apparatus. Accordingly, the operator can understand in real time that the region is irradiated with a modulation laser beam having a certain light intensity distribution waveform.

In the crystallization process, a XeCl excimer laser apparatus, which is the light source, emits a laser beam having a wavelength of 308 nm and a pulse width of 30 ns. The light intensity of the pulsed laser beam is adjusted to a setting value by the attenuator, and the laser beam is incident on the illumination optical system 53. The homogenized pulsed laser beam is supplied from the illumination optical system 53. The phase modulation element 52 is irradiated with the homogenized pulsed laser beam, and a pulsed laser beam having the reversed-peak-pattern-shaped light intensity distribution shown in FIG. 31C is supplied.

The laser beam is optically adjusted through the imaging optical system 54. Finally, the amorphous semiconductor thin film on the processed substrate 55 is irradiated with a laser beam having the desired reversed-peak-pattern-shaped beam profile waveform. Therefore, the crystallization is performed during a process in which the light acceptance region of the amorphous semiconductor thin film is melted and solidified.

The processed substrate 55 is one in which the underlying film, the amorphous silicon film (semiconductor layer), and the capping film are sequentially formed, for example, on the glass substrate for liquid crystal display by a Chemical Vapor Deposition (CVD) technique. The underlying insulator film is made of an insulating material such as SiO₂. The underlying insulator film prevents the amorphous silicon film and the glass substrate from directly contacting each other, to avoid mixing foreign materials such as Na in the glass substrate into the amorphous silicon film, and also prevents the heat of the amorphous silicon film at the melting temperature from transferring directly to the glass substrate. The amorphous silicon film is the semiconductor film to be crystallized, and is a non-single crystal film such as an amorphous semiconductor film or polycrystalline semiconductor film.

The non-single crystal film is not limited to a semiconductor film, and a film made of a non-single crystal material such as a non-single crystal metal may be used as the non-single crystal film. Preferably, an insulating film such as an SiO₂ film is deposited as the capping film on the amorphous silicon film. The capping film is heated by part of the light beam incident on the amorphous silicon film, and the heat is accumulated in the capping film (heat accumulation effect). In the case where the capping film is eliminated, when the incidence of the light beam is blocked, the temperature is relatively rapidly lowered in the high-temperature portion of the irradiated surface of the amorphous silicon film. However, the heat accumulation effect suppresses the lowering of the temperature to promote a large-grain-size crystal growth in a lateral direction. That is, during the lowering of temperature, a temperature distribution corresponding to the weak and strong light intensity distribution formed by a position modulation element is formed in the capping film, and the temperature is lowered while the temperature distribution is retained. Accordingly, a position whose temperature reaches the solidification temperature is sequentially moved to form the lateral crystal growth. In lateral crystal growing, the crystal is radially grown from the crystallization start point to form a square crystallized grain.

The crystallization process is performed sequentially in other regions of the processed substrate 55 by moving the substrate stage 56 for each pulsed laser beam irradiation. The crystallization is repeated by shifting the irradiation region, which enables large-area crystallization.

Embodiments of the invention will be described below. However, the invention is not limited to the following embodiments.

### First Embodiment

FIG. 33 is an explanatory view showing a placement method in which an N-ch TFT is placed in one crystal grain of a two-dimensional growth crystal grain in a first embodiment of the invention. In FIG. 33, the letter L₁ designates a channel length direction, the letter L₂ designates a crystal growth direction, the letter P designates a channel center position, the letter S₁ designates a neighborhood of a crystal growth start point (central portion of the crystal growth region), the letter S₂ (shaded portion) designates a lateral crystal growth region, and the letter S₃ designates a neighborhood of a crystal growth end point. At this point, a distance from the crystal growth start point to the neighborhood of the crystal growth start point is 1.0 μm, and a distance to the neighborhood of the crystal growth end point is 3.5 μm. Although not shown, TFT 11 includes a thin semiconductor film, a source region (S) and a drain region (D) which are formed on the semiconductor film separately from each other, and a gate electrode (G) which is formed on a channel region between the source region (S) and the drain region (D) with a gate insulator interposed therebetween. In FIG. 33, the letter E designates a channel region side end portion of TFT 11.

In FIG. 33, a channel side end portion E (boundary portion between a channel region and a source region or a drain region) of TFT 11 is provided at a position of 1 μm to 3.5 μm away from the crystal growth start position. This arrangement enables good TFT characteristics and decreased fluctuation. The channel position of TFT 11 is located neither on the X-axis nor the Y-axis. However, because the channel length direction L₁ of TFT 11 is parallel to the X-axis, the crystal growth direction L₂ and the TFT channel length direction L₁ are disposed with a given angle.

In the first embodiment of the invention, the channel side end portion E of TFT 11 is disposed at a position of 1 μm to 3.5 μm away from the crystal growth start position. Accordingly, the merit of TFT production with a two-dimensional growth crystal grain having the above-described arrangement can be maximized. As a result, the electric characteristics become better than those of a TFT produced with a one-dimensional growth crystal, and the fluctuation can be minimized.

### Second Embodiment

FIG. 34 is an explanatory view showing a placement method in which an N-ch TFT is placed in one crystal grain of a two-dimensional growth crystal grain in a second embodiment of the invention. As the same letters as those of FIG. 33 are used, a description thereof will be omitted. In FIG. 34, the channel side end portion E of a TFT is disposed at a position of 1 μm to 3.5 μm away from the crystal growth start position. Similarly to the first embodiment, the TFT channel position is located neither on the X-axis nor Y-axis. The second embodiment differs from the first embodiment in that the TFT channel length direction is set so as to be parallel to the crystal growth direction at the TFT channel center position. This arrangement enables good TFT characteristics and decreased fluctuation.

### Third Embodiment

FIG. 35 is an explanatory view showing a placement method in which an N-ch TFT is placed in one crystal grain of a two-dimensional growth crystal grain in a third embodiment of the invention. As the same letters as those of FIG. 33 are used, a description thereof will be omitted. In FIG. 35, the channel side end portion E of a TFT is disposed at a position of 1 μm to 3.5 μm away from the crystal growth start position. In FIG. 35, because the TFT channel position is located on the X-axis, the crystal growth direction is parallel to the X-axis, and the TFT channel length direction is also disposed in parallel with the X-axis. Accordingly, similarly to the second embodiment, the crystal growth direction and the TFT channel length direction are parallel to each other. This arrangement enables good TFT characteristics and decreased fluctuation.

### Fourth Embodiment

FIG. 36 is an explanatory view showing a placement method in which an N-ch TFT is placed in one crystal grain of a two-dimensional growth crystal grain in a fourth embodiment of the invention. As the same letters as those of FIG. 33 are used, a description thereof will be omitted. In FIG. 36, the channel side end portion E of TFT is disposed at a position of 1 μm to 3.5 μm away from the crystal growth start position. This arrangement enables good TFT characteristics and decreased fluctuation. However, in FIG. 36, because the TFT channel position is located on the Y-axis, the TFT channel length direction is parallel to the X-axis although the crystal growth direction is parallel to the Y-axis. Accordingly, the crystal growth direction and the TFT channel length direction are disposed perpendicularly to each other.

### Fifth Embodiment

FIG. 37 is an explanatory view showing a placement method in which an N-ch TFT is placed in one crystal grain of a two-dimensional growth crystal grain in a fifth embodiment of the invention. As the same letters as those of FIG. 33 are used, a description thereof will be omitted. In FIG. 37, the letter 0 designates an angle formed between a crystal growth direction L₂ and a TFT channel length direction. In FIG. 37, the channel side end portion E of a TFT is disposed at a position of 1 μm to 3.5 μm away from the crystal growth start position. This arrangement enables good TFT characteristics and decreased fluctuation. However, because the TFT channel position is located on the X-axis, the TFT channel length direction is not parallel to the X-axis although the crystal growth direction is parallel to the X-axis. Therefore, similarly to the first embodiment, the crystal growth direction and the TFT channel length direction are disposed with a given angle. Assuming that θ is the angle, a TFT is disposed such that θ falls within a range of 0 degrees to 45 degrees, 100 degrees to 225 degrees, or 300 degrees to 320 degrees.

### Sixth Embodiment

FIG. 38 is an explanatory view showing a placement method in which a P-ch TFT is placed in one crystal grain of a two-dimensional growth crystal grain in a sixth embodiment of the invention. As the same letters as those of FIGS. 33 and 37 are used, a description thereof will be omitted. In FIG. 38, the channel side end portion E of TFT is disposed at a position of 1 μm to 3.5 μm away from the crystal growth start position. This arrangement enables good TFT characteristics and decreased fluctuation. However, the TFT channel length direction is parallel to the X-axis though the TFT channel position is located on neither the X-axis nor the Y-axis. Therefore, the crystal growth direction and the TFT channel length direction are disposed with a given angle.

### Seventh Embodiment

FIG. 39 is an explanatory view showing a placement method in which a P-ch TFT is placed in one crystal grain of a two-dimensional growth crystal grain in a seventh embodiment of the invention. As the same letters as those of FIGS. 33 and 37 are used, a description thereof will be omitted. In FIG. 39, the channel side end portion E of TFT is disposed at a position of 1 μm to 3.5 μm away from the crystal growth start position. In FIG. 39, similarly to the first embodiment, the TFT channel position is located on neither the X-axis nor the Y-axis. The seventh embodiment differs from the first embodiment in that the TFT channel length direction is set so as to be parallel to the crystal growth direction at the TFT channel center position. This arrangement enables good TFT characteristics and decreased fluctuation.

### Eighth Embodiment

FIG. 40 is an explanatory view showing a placement method in which a P-ch TFT is placed in one crystal grain of a two-dimensional growth crystal grain in an eighth embodiment of the invention. However, the same letter as that of FIG. 33 is designated by the same letter, and the description will be omitted. In FIG. 40, the channel side end portion E of TFT is disposed at a position of 1 μm to 3.5 μm away from the crystal growth start position. In the eighth embodiment, because the TFT channel position is located on the X-axis, the crystal growth direction is parallel to the X-axis, and the TFT channel length direction is also disposed in parallel to the X-axis. Accordingly, in the eighth embodiment, similarly to the second embodiment, the crystal growth direction and the TFT channel length direction are parallel to each other. This arrangement enables good TFT characteristics and decreased fluctuation.

### Ninth Embodiment

FIG. 41 is an explanatory view showing a placement method in which a P-ch TFT is placed in one crystal grain of a two-dimensional growth crystal grain in a ninth embodiment of the invention. As the same letters as those of FIG. 33 are used, a description thereof will be omitted. In FIG. 41, the channel side end portion E of TFT is disposed at a position of 1 μm to 3.5 μm away from the crystal growth start position. This arrangement enables good TFT characteristics and decreased fluctuation. However, in the ninth embodiment, because the TFT channel position is located on the Y-axis, the TFT channel length direction is parallel to the X-axis although the crystal growth direction is parallel to the Y-axis. Therefore, the crystal growth direction and the TFT channel length direction are disposed perpendicularly to each other.

### Tenth Embodiment

FIG. 42 is an explanatory view showing a placement method in which a P-ch TFT is placed in one crystal grain of a two-dimensional growth crystal grain in a tenth embodiment of the invention. As the same letters as those of FIG. 33 are used, a description thereof will be omitted. In FIG. 42, the channel side end portion E of TFT is disposed at a position of 1 μm to 3.5 μm away from the crystal growth start position. This arrangement enables good TFT characteristics and decreased fluctuation. However, in the tenth embodiment, because the TFT channel position is located on the X-axis, the TFT channel length direction is not parallel to the X-axis although the crystal growth direction is parallel to the X-axis. Therefore, similarly to the first embodiment, the crystal growth direction and the TFT channel length direction are disposed with a given angle. Assuming that 0 is the angle, a TFT is disposed such that 0 falls within a range of 0° to 45°, 100° to 225°, or 3000 to 320°.

### Eleventh Embodiment

An example in which the thin film transistors obtained by the above-described embodiments are actually applied to an active matrix liquid crystal display apparatus will be described with reference to FIG. 43. FIG. 43 is a view showing an example of an active matrix display apparatus in which the thin film transistor is used. A display apparatus 61 has a panel structure including a pair of insulating substrates 62 and 63 and an electro-optic material 64 retained between the insulating substrates. A liquid crystal material is widely used as the electro-optic material 64. A pixel array unit 65 and a drive circuit unit are integrally formed in the lower-side insulating substrate 61. The drive circuit unit is divided into a vertical drive circuit 66 and a horizontal drive circuit 67.

An external connecting terminal portion 68 is formed at an upper end of a peripheral portion of the insulating substrate 62. The terminal portion 68 is connected to the vertical drive circuit 66 and the horizontal drive circuit 67 through an interconnection 69. Gate interconnections 70 are formed in rows on the pixel array unit 65 while signal interconnections 71 are formed in columns on the pixel array unit 65. A pixel electrode 72 and a thin film transistor (TFT) 73 which performs switching drive of the pixel electrode 72 are formed in an intersection portion of the interconnections 70 and 71. A gate electrode of TFT 73 is connected to the corresponding gate interconnection 70, a drain region is connected to the corresponding pixel electrode 72, and a source region is connected to the corresponding signal interconnection 71. The gate interconnection 70 is connected to the vertical drive circuit 66, and the signal interconnection 71 is connected to the horizontal drive circuit 67.

In the display apparatus 61 according to the eleventh embodiment, TFT 73 which performs switching drive of the pixel electrode 72 and TFTs included in the vertical drive circuit 66 and horizontal drive circuit 67 are formed in the crystal growth regions, so that the mobility is enhanced compared with the conventional technique. Accordingly, not only the drive circuit but also the higher-performance processing circuit can integrally be formed.

The thin film transistor of the invention is expected to be applied to a display unit, a scanning unit, a control unit, and the like of a display apparatus such as a liquid crystal display or electroluminescence display, and is utilized to produce a high-performance display apparatus.

The invention is not limited to the above-described embodiments, and various modifications of the constituents can be made in the implementation stage without departing from the scope of the invention. Various inventions can also be made by appropriately combining plural constituents disclosed in the embodiments. For example, some constituents may be eliminated from all the constituents disclosed in the embodiment. Additionally, the constituents of different embodiments may be appropriately combined.

What is claimed is:

1. A thin film transistor comprising a crystal growth region in which a crystal is two-dimensionally grown on a plane, a source region and a drain region in which at least a channel region is provided so as to be aligned with the crystal growth region, and a gate electrode which is formed on a channel region between the source region and the drain region through a gate insulator film,
wherein a side end portion on the channel region side of the source region or drain region is aligned with a position located within a range of 1 μm to 3.5 μm away from a crystal growth start position.

2. The thin film transistor according to claim 1, wherein the source region, the drain region, and the channel region are formed in a crystal growth region of a virtual region passing through a central portion of the crystal growth region and a middle of each side.

3. A thin film transistor comprising a crystal growth region in which a crystal is two-dimensionally grown on a plane, a source region and a drain region in which at least a channel region is provided so as to be aligned with the crystal growth region, and a gate electrode which is formed on a channel region between the source region and the drain region through a gate insulator film,
wherein a current is passed in a crystal growth direction of the crystal growth region in the thin film transistor, and the thin film transistor is formed in a region of one of angles formed between the crystal growth direction and a current direction ranging from 0° to 45°, 135° to 225°, and 315° to 360°.

4. The thin film transistor according to any one of claims 1 to 3, wherein the crystal growth region in which the crystal is two-dimensionally grown on the plane is radially grown.

5. A display apparatus comprising the thin film transistor according to any one of claims 1 to 3.
